(19) United States
(12) Patent Application Publication
(10) Pub. No.: US 2025/0372534 A1
(43) Pub. Date: Dec. 4, 2025

(54) SEMICONDUCTOR PACKAGE AND METHOD OF MANUFACTURING SEMICONDUCTOR PACKAGE

(71) Applicant: Taiwan Semiconductor Manufacturing Company, Ltd., Hsinchu (TW)

(72) Inventors: Hung-Min Chang, Hsinchu City (TW); Chien-Chang Lin, New Taipei City (TW); Wensen Hung, Hsinchu County (TW); Hsuan-Cheng Kuo, Hsinchu County (TW); Shih-Hui Wang, New Taipei City (TW); Tzu-Shiun Sheu, Hsinchu (TW)

(73) Assignee: Taiwan Semiconductor Manufacturing Company, Ltd., Hsinchu (TW)

(21) Appl. No.: 18/679,311

(22) Filed: May 30, 2024

(51) Int. Cl. H01L 23/00; H01L 21/50; H01L 23/04; H01L 23/31; H01L 23/498; H01L 25/065

(52) U.S. Cl. CPC H01L 23/562; H01L 21/50; H01L 23/04; H01L 23/3121; H01L 23/49833; H01L 25/0655; H01L 24/16; H01L 24/32; H01L 24/73; H01L 2224/16225; H01L 2224/32225; H01L 2224/73204; H01L 2924/1815

(57) ABSTRACT

A semiconductor package includes a substrate, a semiconductor device disposed over the substrate, a ring structure bonded to the substrate, and a lid structure. The ring structure includes a main portion surrounding the semiconductor device and a cantilever portion extended toward the semiconductor device and bonded to a top surface of the semiconductor device. The lid structure is bonded to the ring structure and includes a contact portion bonded to the top surface of the semiconductor device.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon. Many integrated circuits are typically manufactured on a single semiconductor wafer. The dies of the wafer may be processed and packaged at the wafer level, and various technologies have been developed for wafer level packaging.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 6 illustrates a cross sectional views of intermediate stages in the manufacturing of a semiconductor package according to some embodiments of the present disclosure.

FIG. 7 illustrates a cross sectional view of the semiconductor package according to some embodiments of the present disclosure.

FIG. 8 illustrates a schematic top view of a semiconductor package according to some embodiments of the present disclosure.

FIG. 9 illustrates a schematic top view of a ring structure of a semiconductor package according to some embodiments of the present disclosure.

FIG. 10 to FIG. 20 illustrates a cross sectional views of intermediate stages in the manufacturing of a semiconductor package according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A semiconductor package and the method of manufacturing a semiconductor package are provided in accordance with various exemplary embodiments. Before addressing the illustrated embodiments specifically, certain advantageous features and aspects of the present disclosed embodiments will be addressed generally. Described below is a semiconductor package including at least one semiconductor device that is bonded to a substrate. In addition, a ring structure is disposed over the substrate and surrounds the semiconductor device with a lid structure covering the ring structure and bonded to the semiconductor device through thermal interface material (TIM) for purposes of shielding, reinforcement, and/or heat dissipation, etc. The ring structure includes a cantilever portion extended toward the semiconductor device and bonded between the semiconductor device and the lid structure for increasing the bonding area between the ring structure and the lid structure.

Generally, there may exist coefficient of thermal expansion (CTE) mismatch between the material typically used for the lid structure (e.g., metal), the material typically used for the semiconductor device (e.g., silicon) and the material used for the substrate (e.g., Ajinomoto Build-up Film, ABF, glass fiber). The CTE mismatch between these materials may cause thermal stress on the semiconductor package, which may result in delamination between the ring structure and the lid structure. Accordingly, with the arrangement of the cantilever portion extended toward the semiconductor device and bonded between the semiconductor device and the lid structure, warpage of the package can be improved, so as to reduce the issues of delamination, warpage, die crack, etc., and the thermal performance of the semiconductor package can be improved. The intermediate stages of forming the semiconductor package are illustrated in accordance with some embodiments. Some variations of some embodiments are discussed. Throughout the various views and illustrative embodiments, like reference numbers are used to designate like elements.

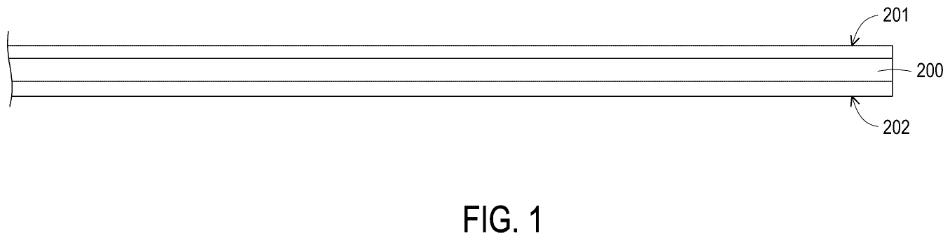

FIG. 1 to FIG. 6 illustrates a cross sectional views of intermediate stages in the manufacturing of a semiconductor package according to some embodiments of the present disclosure. Referring to FIG. 1, a substrate 200 may be used to provide electrical connection between components or devices packaged in the semiconductor device/package and an external electronic device (not shown). In some embodiments, the substrate 200 may be a bulk semiconductor substrate, a semiconductor-on-insulator (SOI) substrate, a germanium-on-insulator (GOI) substrate, or the like. The semiconductor substrate is formed of a elementary semiconductor such as silicon or germanium; a compound semiconductor such as silicon germanium, silicon carbide, gallium arsenic, gallium phosphide, indium phosphide, indium arsenide, and/or indium antimonide; an alloy semiconductor such as SiGe, GaAsP, AlInAs, AlGaAs, GaInAs, GaInP, and/or GaInAsP; or combinations thereof. Alternatively, the package substrate 10 may include a printed circuit board (PCB), a ceramic substrate, or another suitable package substrate, in accordance with some other embodiments. The substrate 200 may be a core or a core-less substrate.

In some embodiments, the substrate 200 has various device elements (not shown). Examples of device elements that are formed in or on the substrate 200 may include transistors (e.g., metal oxide semiconductor field effect transistors (MOSFET), complementary metal oxide semiconductor (CMOS) transistors, bipolar junction transistors (BJT), high voltage transistors, high-frequency transistors, p-passage and/or n-passage field-effect transistors (PFETs/NFETs), etc.), diodes, resistors, capacitors, inductors, and/or other applicable device elements. Various processes can be performed to form the device elements, such as deposition, etching, implantation, photolithography, annealing, and/or other suitable processes. The substrate 200 may also have one or more circuit layers (not shown) used to electrically connect the device elements and semiconductor devices that are subsequently attached.

The substrate 200 may generally have a rectangular (or square) shape in a plan view, depending on design requirements, although other shapes may also be used. The substrate 200 may have opposite surfaces 201 and 202, which may be substantially parallel to each other. The surface 201 (i.e., the top surface shown) may be used to receive and bond other semiconductor devices (which will be described in detail below) of the semiconductor package. The surface 202 (i.e., the bottom surface shown) may have several electrical connectors (not shown) formed thereon to enable electrical connection between the entire semiconductor package and an external electronic device such as a PCB, or the like. In some embodiments, the electrical connectors may be or include solder balls such as tin-containing solder balls. The solder balls can be bonded to the substrate 200 using a reflow process.

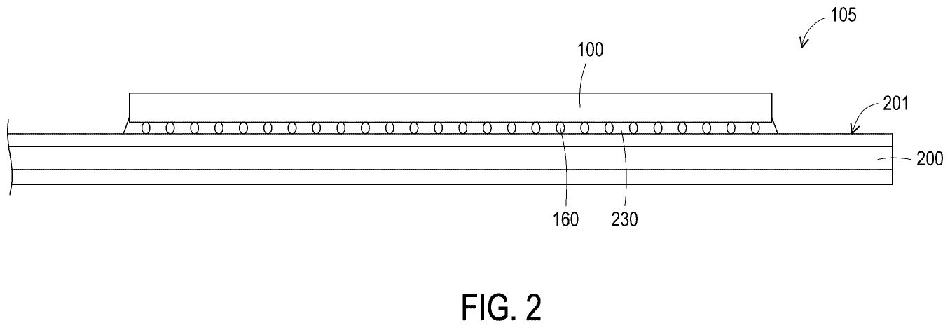

With now reference to FIG. 2, at least one semiconductor device 100 is provided onto the surface 201 of the substrate 200. In some embodiments, the semiconductor device 100 is a package device, which includes a plurality of dies encapsulated by an encapsulating material, or includes an interposer and a plurality of different types of dies disposed over the interposer. For illustration purposes, the semiconductor die 100 herein is illustrated in an abstract form as a blank block, and examples of the detail structure of the semiconductor die will be described in detail later.

In some embodiments, the semiconductor device 100 may be bonded on the substrate 200 through flip-chip bonding (e.g., solder bonding) through a plurality of conductive structures 160 as shown in FIG. 2. It should be appreciated that the embodiments described here are provided for illustrative purposes, and other suitable bonding methods can also be used in different embodiments. In some embodiments, each of the conductive structures 160 may include a metal pillar and a metal cap layer (such as a solder cap) over the metal pillar. The conductive structures 160 including the metal pillars and the metal cap layers are sometimes referred to as micro bumps. In some embodiments, the metal pillars may include a conductive material such as copper, aluminum, gold, nickel, palladium, the like, or a combination thereof, and may be formed by sputtering, printing, electroplating, electroless plating, CVD, or the like. The metal pillars may be solder-free and have substantially vertical sidewalls. The metal cap layers may include nickel, tin, tin-lead, gold, copper, silver, palladium, indium, nickel-palladium-gold, nickel-gold, the like, or a combination thereof, and may be formed by a plating process such as an electroplating process. One of ordinary skill in the art would appreciate that the above conductive structures 160 examples are provided for illustrative purposes, and other structures of the conductive structures 160 may also be used.

In some embodiments, the semiconductor dies 100 are bonded to the substrate 200 through a reflow process. During the reflow, the conductive structures 160 are in contact with the exposed contact pads of the semiconductor die 100 and the exposed contact pads of the substrate 200, respectively, to physically and electrically couple the semiconductor die 100 to the substrate 200.

In some embodiments, an underfill material 230 is further formed over the substrate 200 to surround and protect the conductive structure 160, and enhances the connection between the semiconductor die 100 to the substrate 200. In some embodiments, the underfill material 230 may further encapsulate a side surface of the redistribution structure 120 to surround and protect the redistribution structure 120. The underfill material 230 may include an epoxy, a resin, a filler material, a stress release agent (SRA), an adhesion promoter, another suitable material, or a combination thereof. In some embodiments, the underfill material 230 is in liquid state and dispensed into the gaps between the semiconductor device 100 and the substrate 200 (for example, by capillary effect) to reinforce the strength of the conductive structure 160 and therefore the overall package structure. After the dispensing, the underfill material 230 is cured. In some embodiments, the underfill material 230 fills the gap between the semiconductor device 100 and the substrate 200, and also has a portion extending into gaps between a plurality of dies in the semiconductor device 100, which will be described in detail below. The structure shown in FIG. 2 including the semiconductor device 100 disposed over the substrate 200 can be referred to as a package structure 105.

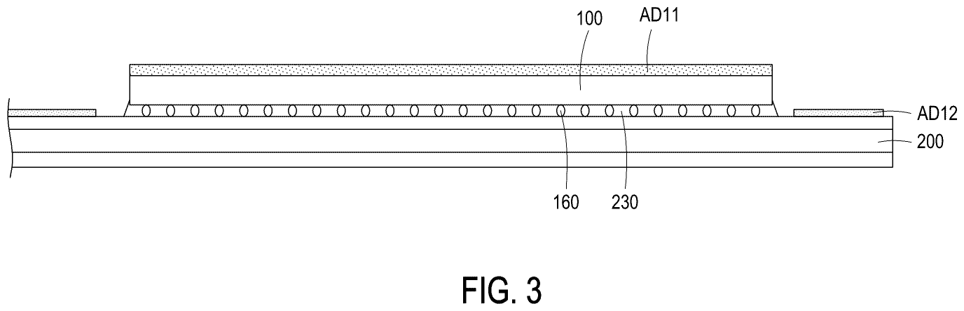

Next, referring to FIG. 3, a (first) adhesive AD11, AD12 are provided over, and may be in physical contact with, the substrate 200 and a top surface of the semiconductor device 100. For example, the first adhesive may include a portion AD11 dispensed on the top surface of the semiconductor device 100, and a portion AD12 dispensed on a periphery portion of the substrate 200 where a ring structure is to be disposed. In some embodiments, the adhesive AD12 dispensed over the substrate 200 may, or may not, form a ring. In accordance with some embodiments, when forming the ring, the adhesive AD12 encircles the semiconductor device 100. The adhesive AD11, AD12 may include thermal interface material (TIM), or the like. The thermal interface material has a good thermal conductivity, which may be greater than about 2 W/m*K, and may be as equal to, or higher than, about 10 W/m*K or 50 W/m*K.

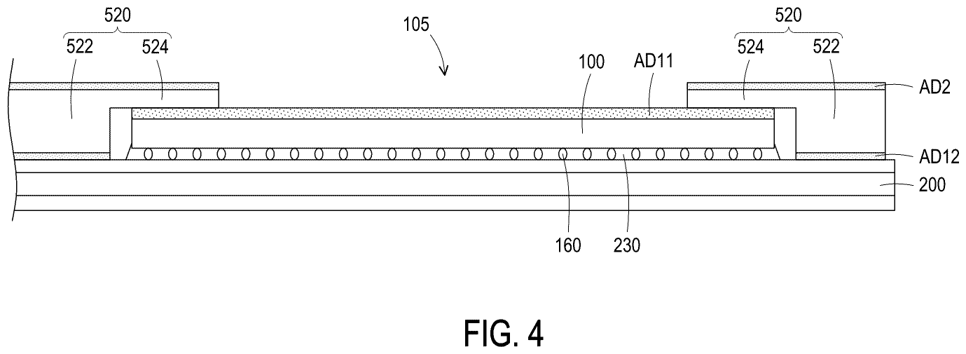

Then, referring to FIG. 4, a ring structure 520 is bonded onto the substrate 200. In some embodiments, the ring structure 520 has a high thermal conductivity greater than about 100 W/m*K, for example, and may be formed using a metal, a metal alloy, or the like. For example, the ring structure 520 may include metals and/or metal alloys selected from the group consisting of Al, Cu, Ni, Co, and the like. The ring structure 520 may also be formed of a composite material selected from the group consisting of silicon carbide, aluminum nitride, graphite, and the like. The ring structure 520 includes a first bottom surface contacting the adhesive AD12, and a second bottom surface adhered to semiconductor device 100 through adhesive AD11. In some embodiments, the materials of the adhesive AD11, AD12 may be different and may be dispensed separately. For example, the adhesive AD12 may have a better adhering ability and a lower thermal conductivity than adhesive AD11. In one embodiment, the adhesive AD12 may have a thermal conductivity lower than about 0.5 W/m*K, but the disclosure is not limited thereto.

In some embodiments, the ring structure 520 includes a main portion 522 and a cantilever portion 524 extending from the main portion 522. The main portion 522 surrounds the semiconductor device 100 and is bonded to the substrate 200 through the adhesive AD12. The cantilever portion 524 is extended toward the semiconductor device 100 and bonded to a first part of the top surface of the semiconductor device 100 through the adhesive AD11. That is, the lower surface of the main portion 522 is bonded to the substrate 200 through the adhesive AD12, and the lower surface of the cantilever portion 524 is bonded to the top surface of the semiconductor device 100 through the adhesive AD11. To be more specific, a cross section of a sidewall of the ring structure 520 is in inverted L shape as shown in FIG. 4, and the ring structure 520 is bonded to the top surface of the package structure 105 (i.e., the first part of the top surface of the semiconductor device 100).

Then, a (second) adhesive AD2 is provided over the cantilever portion 524 and the main portion 522. That is, the adhesive AD2, which may be substantially similar to adhesive AD11, AD12, may be dispensed over the top surface of the ring structure 520 including the cantilever portion 524 and the main portion 522. The adhesive AD2 may include thermal interface material (TIM), or the like. The thermal interface material has a good thermal conductivity, which may be greater than about 2 W/m*K, and may be as equal to, or higher than, about 10 W/m*K or 50 W/m*K. In the embodiment, the adhesive AD2 may have a better adhering ability and a lower thermal conductivity than adhesive AD11. For example, the adhesive AD2 may have a thermal conductivity lower than about 0.5 W/m*K, but the disclosure is not limited thereto.

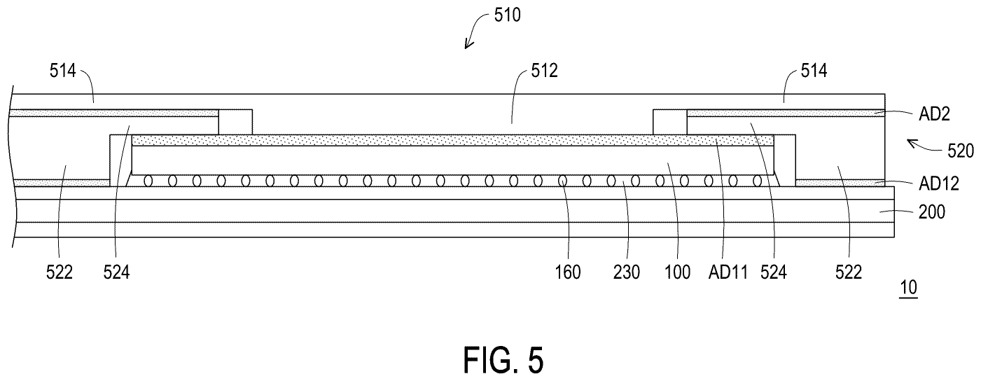

Referring to FIG. 5, in some embodiments, the lid structure 510 is bonded over the ring structure 520 and a second part of the top surface of the semiconductor device 100. That is, the lid structure 510 is mounted over the ring structure 520 through the adhesive AD2 and is bonded to the semiconductor device 100 through the adhesive AD11. The lid structure 510 may be formed of substantially similar materials as the ring structure 520, which have a high thermal conductivity, for example, between about 200 W/m·K to about 400 W/m·K or more. In some embodiments, the lid structure 510 has a high thermal conductivity greater than about 100 W/m*K, for example, and may be formed using a metal, a metal alloy, or the like. For example, the lid structure 510 may include metals and/or metal alloys selected from the group consisting of Al, Cu, Ni, Co, and the like. The lid structure 510 may also be formed of a composite material selected from the group consisting of silicon carbide, aluminum nitride, graphite, and the like.

In some embodiments, the lid structure 510 includes a contact portion 512, which is bonded to the top surface of the semiconductor device 100 through the adhesive AD11. In other words, the adhesive AD11, such as a thermal interface material, is disposed between the contact portion 512 and the semiconductor device 100 for thermally coupling the semiconductor device 100 and the lid structure 510. In some embodiments, the lid structure 510 further includes a flange portion 514 connecting the contact portion 512, and the flange portion 514 is bonded to the cantilever portion 524 and the main portion 522 of the ring structure 520 through the adhesive AD2. In some embodiments, a thickness of the contact portion 512 is greater than a thickness of the flange portion 514. That is, the contact portion 512 is protruded from the flange portion 514 to be bonded with the top surface of the semiconductor device 100. At this point, manufacture of a semiconductor package 10 may be substantially done.

With this arrangement, the cantilever portion 524 of the ring structure 520 is extended toward the semiconductor device 100 to be bonded with a part of top surface of the semiconductor device 100, so that an area of an upper surface of the ring structure 520 bonding to the lid structure 510 is greater than an area of a lower surface of the ring structure 520 bonding to the substrate 200. Accordingly, the bonding strength between the ring structure 520 and the lid structure 510 is increased. Moreover, the cantilever portion 524 is bonded between the semiconductor device 100 and the lid structure 510, so the bonding strength between the semiconductor device 100, the ring structure 520, and the lid structure 510 can be improved, so as to reduce issues of warpage of the semiconductor package 10, delamination between the semiconductor device 100, the ring structure 520, and the lid structure 510, cracks or any kind of stress damages to the semiconductor package 10 (e.g., cracks in die or encapsulating material), or the like.

In some embodiments, material of the ring structure 520 may be different from that of the lid structure 510 for serving different purposes. For example, the ring structure 520 may be stiffer than the lid structure for mainly providing reinforcement, while a thermal conductivity of the lid structure 510 may be greater than that of the ring structure 520 for mainly providing heat dissipation. In one embodiment, a young's modulus of the ring structure 520 may be greater than a young's modulus of the lid structure 510. For example, a young's modulus ratio of the lid structure 510 to the ring structure 520 is from about 0.3 to about 0.9. In one embodiment, a coefficient of thermal expansion (CTE) of the lid structure 510 is greater than a CTE of the ring structure 520. For example, a CTE ratio of the lid structure 510 to the ring structure 520 is from about 2.2 to about 6. The disclosure is not limited thereto.

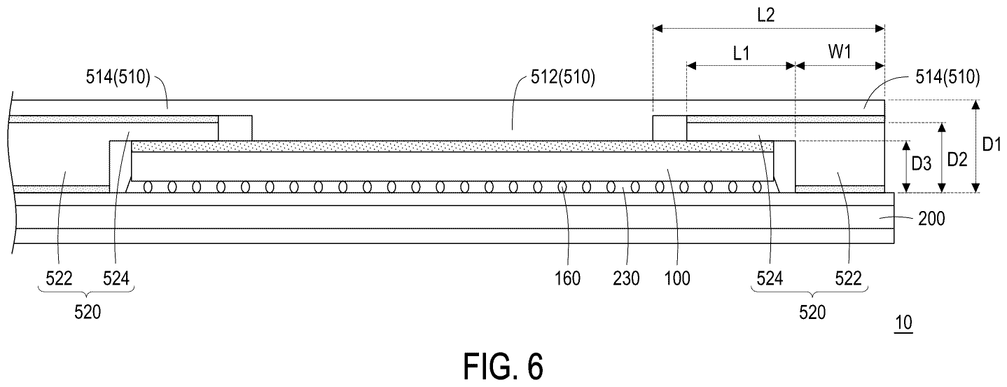

Referring to FIG. 6, in some embodiments, a length ratio of the cantilever portion 524 to the main portion 522 (i.e., L1/W1) ranges from about 0.25 to about 10. If the length ratio (L1/W1) is smaller than 0.25, the bonding strength between the ring structure 520 and the lid structure 510 may not be enough, which may result in delamination. On the other hand, if the length ratio (L1/W1) is greater than 10, the bonding strength between the ring structure 520 and the lid structure 510 may be too strong, which may worsen the warpage since the CTE of the lid structure 510 is higher than the CTEs of the ring structure 520 and the semiconductor device 100. For example, the length L1 of the cantilever portion 524 may range from about 0.5 mm to about 33 mm. In one embodiment, the length L1 of the cantilever portion 524 is about 3 mm. The length W1 of the main portion 522 ranges from about 1.5 mm to about 3 mm. In one embodiment, the length W1 of the main portion 522 is about 2 mm.

In some embodiments, a length ratio of the flange portion 514 of the lid structure 510 to the cantilever portion 524 of the ring structure 520 (i.e., L2/L1) ranges from about 1.5 to about 15. If the length ratio (L2/L1) is smaller than 1.5, the flange portion 514 may be too short, which may not leave enough gap between the contact portion 512 and cantilever portion 524. On the other hand, if the length ratio (L2/L1) is greater than 15, the flange portion 514 may be too long, which may result in the contact portion 512 being too small and leads to delamination between the lid structure 510 and the semiconductor device 100. In one embodiment, the length L1 of the cantilever portion 524 may range from about 0.5 mm to about 33 mm, and the length L2 of the flange portion 514 ranges from about 3.5 mm to about 35.85 mm. For example, the length L2 of the flange portion 514 is about 5.85 mm.

In some embodiments, an overall thickness D2 of the ring structure 520 may range from about 1 mm to about 4 mm. For example, the overall thickness D2 of the ring structure 520 is about 1.5 mm. The overall thickness D2 minus the thickness of the cantilever portion 524, referred to as thickness D3, may range from about 0.5 mm to about 3 mm. For example, the thickness D3 is about 1 mm. A thickness ratio of the overall thickness D2 of the ring structure 520 to the thickness D3 ranges from about 1.1 to 3.

In some embodiments, an overall thickness D1 of the ring structure 520 bonding with the lid structure 510 may range from about 1.5 mm to about 6 mm. For example, the overall thickness D1 of the ring structure 520 bonding with the lid structure 510 is about 2 mm. Accordingly, a thickness of the flange portion 514, referred to as the thickness (D1-D2), may range from about 0.1 mm to about 0.5 mm. A thickness ratio of the flange portion 514 to the cantilever portion 524, referred to as the thickness ratio (D1-D2)/(D2-D3), may range from about 0.1 to about 2. With such configuration, the bonding strength between the ring structure 520 and the lid structure 510 can be improved so that delamination between the semiconductor device 100, the ring structure 520 and the lid structure 510 can be avoided, while the warpage of the semiconductor package 10 can be reduced to an acceptable degree.

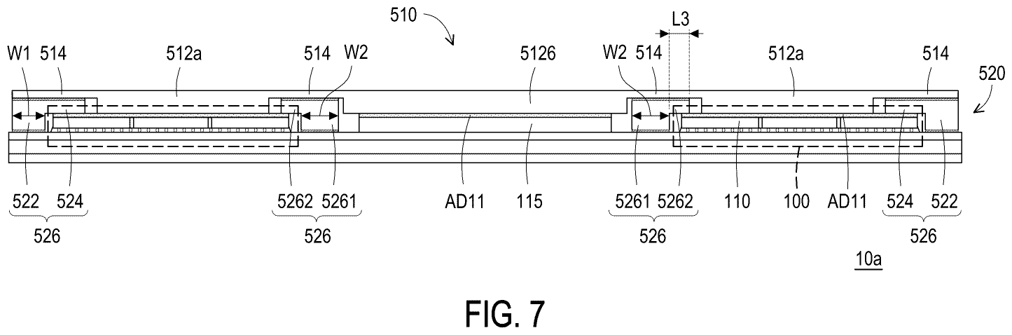

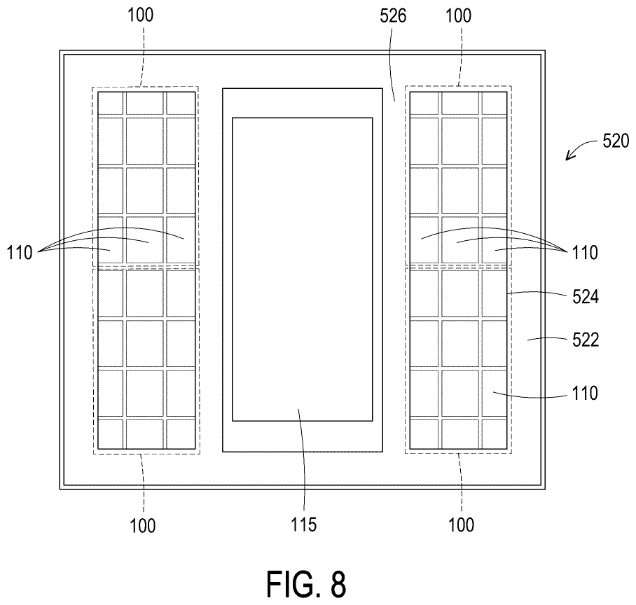

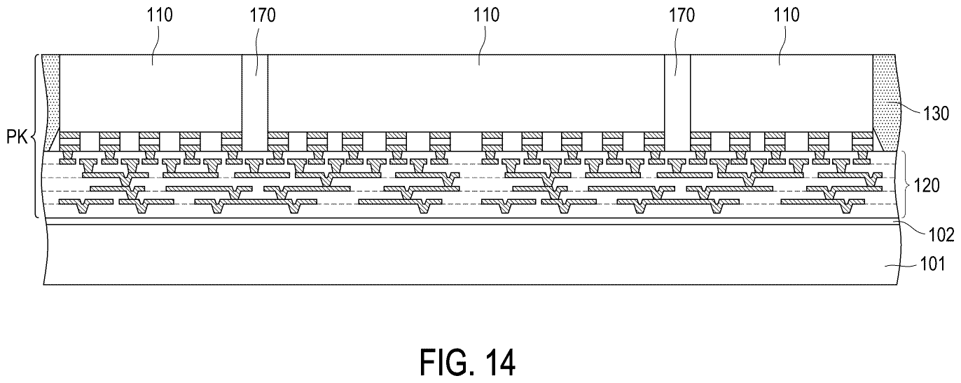

FIG. 7 illustrates a cross sectional view of the semiconductor package according to some embodiments of the present disclosure. FIG. 8 illustrates a schematic top view of a semiconductor package according to some embodiments of the present disclosure. Referring to FIG. 7 and FIG. 8, in some embodiments, the semiconductor device that is disposed over the substrate 200 may include a plurality of first dies 110 surrounding a second die 115. In detail, the semiconductor device may include a device package 100 having a plurality of first dies 110 encapsulated by an encapsulating material (e.g., the encapsulating material 130 shown in FIG. 14) and a second die 115 arranged in a side by side manner.

In some embodiments, the second die 115 includes a logic die, which may be a central processing unit (CPU) die, a graphic processing unit (GPU) die, a mobile application die, a micro control unit (MCU) die, an input-output (IO) die, a baseband (BB) die, an application processor (AP) die, or the like. The second die 115 may also include system on chip (SOC) dies. In some embodiments, the first dies 110 include memory dies such as dynamic random access memory (DRAM) dies, static random access memory (SRAM) dies, high bandwidth memory (HBM) dies, or the like. The memory dies may be discrete memory dies, or may be in the form of a die stack that includes a plurality of stacked memory dies.

Each of the dies 110, 115 may include a semiconductor substrate and a plurality of integrated circuit devices (not shown, including transistors, diodes, passive devices, etc.) formed on the semiconductor substrate. Also, several contact pads interconnected to the internal circuits may be exposed at the respective active surface (the bottom surface shown) of the dies 110, 115, to which external electrical connections are made. Each of the dies 110, 115 can be obtained, for example, by sawing or dicing a semiconductor wafer (with several IC dies formed thereon) along scribed lines to separate the semiconductor wafer into a plurality of individual semiconductor dies.

Depending on actual needs, the dies 110, 115 may have any suitable arrangement above the substrate 200. The substrate 200 may include an organic substrate, a silicon substrate, or the like. The substrate 200 may also include conductive features therein, such as conductive lines and conductive vias (sometimes collectively referred to as a redistribution line (RDL) structure), to interconnect contact pads (not shown) on tow opposite surfaces of the substrate 200. The materials and formation method of the substrate 200 are well known in the art and therefore not described herein. In some embodiments, the die 115 and the device package 100 including the dies 110 may be bonded on the substrate through flip-chip bonding (e.g., solder bonding). It should be appreciated that the embodiments described here are provided for illustrative purposes, and other suitable bonding methods can also be used in different embodiments.

In this embodiment, the lid structure 510 may include a plurality of contact portions 512a, 5126 for being bonded to the device package 100 and the second die 115 respectively. For example, in the present embodiment, the device packages 100 are disposed on two opposite sides of the second die 115, and the contact portions 512a are bonded to the device packages 100 respectively, while the contact portions 5126 is bonded to the top surface of the second die 115 through adhesive AD11, for example.

In some embodiments, the ring structure 520 may further include a rib 526 extended across a space surrounded by the main portion 522. In the embodiment, the rib 526 is disposed between the second die 115 and the plurality of first dies 110. To be more specific, the device packages 100 including the first dies 110 are disposed on two opposite sides of the second die 115. Accordingly, the main portion 522 of the ring structure 520 surrounds the device packages 100 and the second die 115 and the rib 526 is extended between the second die 115 and the device packages 100 (including the first dies) as shown in FIG. 8 for providing reinforcement to the semiconductor package 10a.

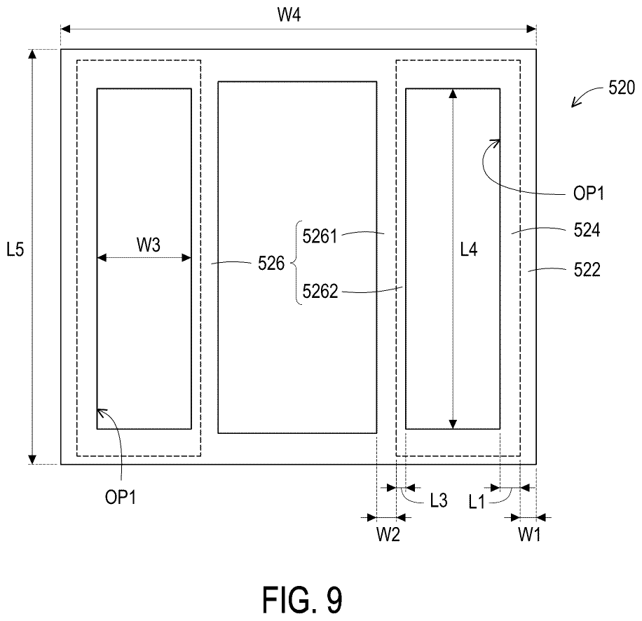

FIG. 9 illustrates a schematic top view of a ring structure of a semiconductor package according to some embodiments of the present disclosure. Referring to FIG. 7 to FIG. 9, in some embodiments, the rib 526 further includes a main body 5261 extended between the second die 115 and the device packages 100 and an upper portion 5262 extended toward and bonded onto the device package 100 of the semiconductor device. In other words, the cross section of the rib 526 is also in an inverted L shape, and the flange portion 514 of the lid structure 510 is bonded to the upper portion 5262 of the rib 526. In one embodiment, a width W2 of the main body 5261 of the rib 526 is substantially greater than a width W1 of the main portion 522 of the ring structure 520 due to the layout of the semiconductor package 10a. For example, the width W2 of the rib 526 ranges from about 1.5 mm to about 4.5 mm. In one embodiment, the width W2 of the rib 526 is about 3 mm. In one embodiment, a length L3 of the upper portion 5262 ranges from about 0.5 mm to about 31.6 mm. In one embodiment, the length L3 of the upper portion 5262 is about 1.6 mm. A ratio of the length L3 of the upper portion 5262 to the width W2 of the main body 5261 ranges from about 0.25 mm to about 10 mm. With such arrangement, the rib 526 is not only configured to provide reinforcement to the semiconductor package 10a, but also help improving the bonding strength between the ring structure 520 and the lid structure 510 and controlling the warpage of the semiconductor package 10a.

Referring to FIG. 7 to FIG. 9, in some embodiments, from a top view, the cantilever portion 524 and the upper portion 5262 of the rib 526 define an opening OP1 for exposing a part of the top surface of the device package 100. Accordingly, in one embodiment, a ratio of an overall length L5 of the ring structure 520 to the length L4 of the opening OP1 ranges from about 1.04 to about 4. A ratio of an overall width W4 of the ring structure 520 to the length W3 of the opening OP1 ranges from about 2.5 to about 10. With such configuration, the bonding strength between the ring structure 520 and the lid structure 510 can be improved so that delamination between the semiconductor device 100, the ring structure 520 and the lid structure 510 can be avoided, while the warpage of the semiconductor package 10 can be reduced to an acceptable degree.

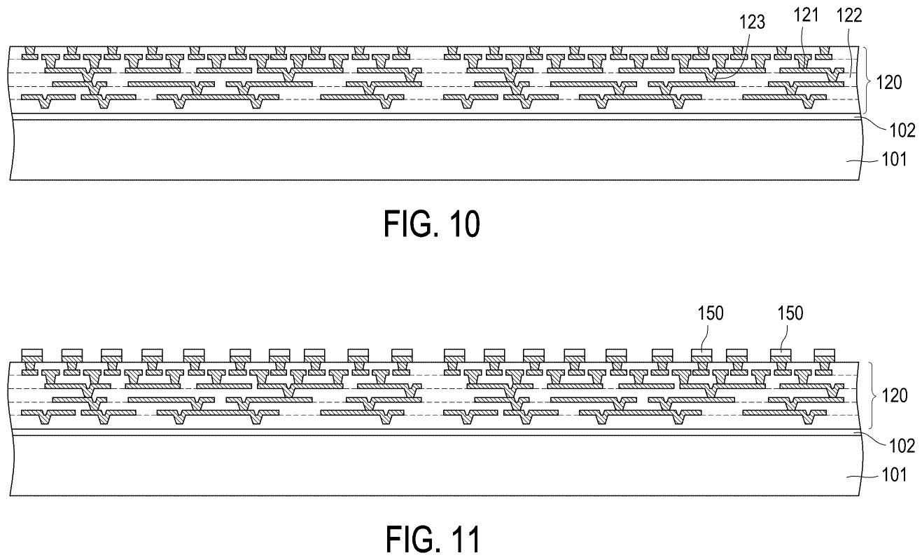

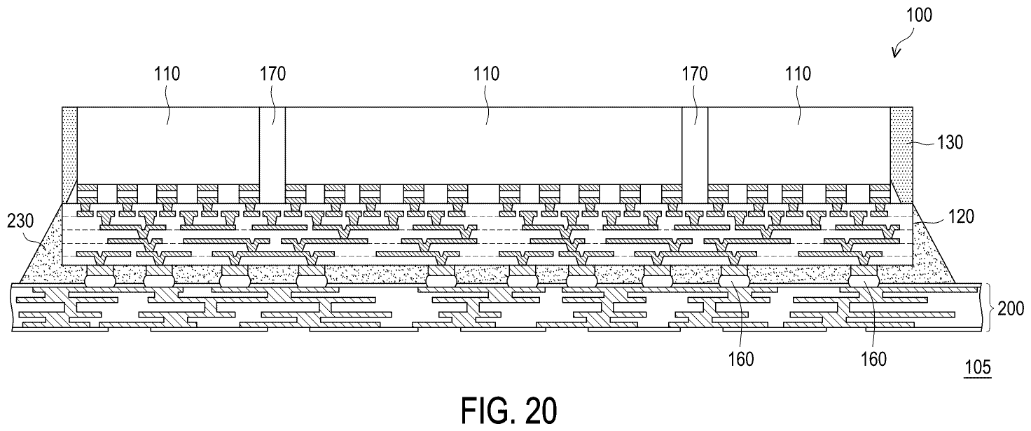

FIG. 10 to FIG. 20 illustrates a cross sectional views of intermediate stages in the manufacturing of a semiconductor package according to some embodiments of the present disclosure. There are various implementations that can be applied to the device package/semiconductor device 100 shown in the previous embodiments. In one embodiment, the device package 100 shown in FIG. 20 including a plurality of (first) dies 110 and an encapsulating material 130 laterally encapsulating the dies 110 is mounted over the substrate 200 to form the package structure 105, so that the ring structure 520 and the lid structure shown in the previous embodiments can be bonded thereon. FIG. 10 to FIG. 20 illustrate manufacturing process of one of the possible implementations of the device package/semiconductor device 100. However, the disclosure is not limited thereto. Other suitable packages and component configurations may also be applied. The device package 100 may be in a wafer form (a reconstructed wafer) in the process. The formation of the device package 100 may include the following steps.

Referring to FIG. 10, in some embodiments, a redistribution structure 120 is formed on a carrier 101. In some embodiments, the carrier 101 includes, for example, silicon based materials, such as glass or silicon oxide, or other materials, such as aluminum oxide, combinations of any of these materials, or the like. The carrier 101 is planar in order to form the redistribution structure 120 thereon and accommodate an attachment of a plurality of dies 110 (not illustrated in FIG. 1 but illustrated and described below with respect to FIG. 3). In some embodiments, an adhesive layer 102 may be placed on the carrier 101 in order to assist in the adherence of overlying structures (e.g., the redistribution structure 120). In an embodiment the adhesive layer 102 may include an ultra-violet glue, which loses its adhesive properties when exposed to ultra-violet light. However, other types of adhesives, such as pressure sensitive adhesives, radiation curable adhesives, epoxies, an Ajinomoto build-up film (ABF), combinations of these, or the like, may also be used. The adhesive layer 102 may be placed onto the carrier 101 in a semi-liquid or gel form, which is readily deformable under pressure.

In accordance with some embodiments of the disclosure, the redistribution structure 120 is formed over the carrier 101 and the adhesive layer 102 (if any). In some embodiments, the redistribution structure 120 may be formed by depositing conductive layers, patterning the conductive layers to form a plurality of redistribution lines (e.g., the redistribution lines 121). The redistribution lines are at least partially covered with dielectric layers (e.g., dielectric layer 122) and the dielectric layers fill the gaps between the redistribution lines and the conductive lines. The vias (e.g., the via 123) are located on the layers of the redistribution structure 120 respectively and extending through the corresponding dielectric layers for interconnecting the redistribution lines at different layers. The material of the redistribution lines may include a metal or a metal alloy including aluminum, copper, tungsten, and/or alloys thereof.

In detail, a seed layer, such as a copper, titanium, or the like, may be deposited over the carrier 101, such as by sputtering or another physical vapor deposition (PVD) process. A photo resist is deposited on the seed layer and patterned to expose portions of the seed layer by photolithography. The pattern is for a metallization layer on the redistribution structure 120. Conductive material of the redistribution lines and the conductive lines, such as copper, aluminum, the like, or a combination thereof, is deposited on the exposed seed layer, such as by electroless plating, electroplating, or the like. The photoresist is removed by an ash and/or flush process. The exposed seed layer removed, such as by a wet or dry etch. The remaining conductive material forms a metallization layer (e.g., the redistribution lines) of the redistribution structure 120. A dielectric layer is deposited over the metallization layer. The material of the dielectric layer may include polymer such as a polyimide, polybenzoxazole (PBO), benzocyclobutene (BCB), the like, or a combination thereof. The dielectric layer can be deposited by a coating process, a lamination process, the like, or a combination thereof. Vias may be formed through the dielectric layer to the metallization layer using acceptable photolithography techniques.

Subsequent metallization layers and dielectric layers may be formed using the same or similar processes as discussed. Conductive material deposited during the formation of a subsequent metallization layer may be deposited in openings of the previously formed dielectric layers to form vias for electrically connecting respective metallization layers. After forming the topmost dielectric layer, via is formed through the topmost dielectric layer for connectors coupled between the redistribution lines, and another semiconductor device, package, die, and/or another substrate. It should be noted that any number of metallization layers and dielectric layers may be formed, and the redistribution structure 120 in this embodiment is illustrated as an example.

With now reference to FIG. 11, in some embodiments, after the redistribution structure 120 is formed, the conductive bumps 150 are provided over the redistribution structure 120. In some embodiments, the conductive bumps 150 may be solder balls, metal pillars, controlled collapse chip connection (C4) bumps, micro bumps, electroless nickel-electroless palladium-immersion gold technique (ENEPIG) formed bumps, combination thereof (e.g., a metal pillar having a solder ball attached thereof), or the like. In the present embodiment, the conductive bumps are micro bumps, for example, and each of the conductive bumps 150 may include a solder layer formed above a copper seed layer. An optional nickel layer may be in between the solder layer and the copper seed layer. The copper seed layer and the nickel layer may act as an UBM and a barrier layer for the formation of solder layer. The solder layer may include an electrically conductive solder material, e.g., Sn, Ni, Au, Ag, Cu, Bi, W, Fe, Ferrite, an alloy or combination thereof, or any other suitable material. One of ordinary skill in the art will recognize that there are many suitable arrangements of materials and layers suitable for the formation of the conductive bumps 150. Any suitable materials or layers of material that may be used for the conductive bumps 150 are fully intended to be included within the scope of the current embodiments.

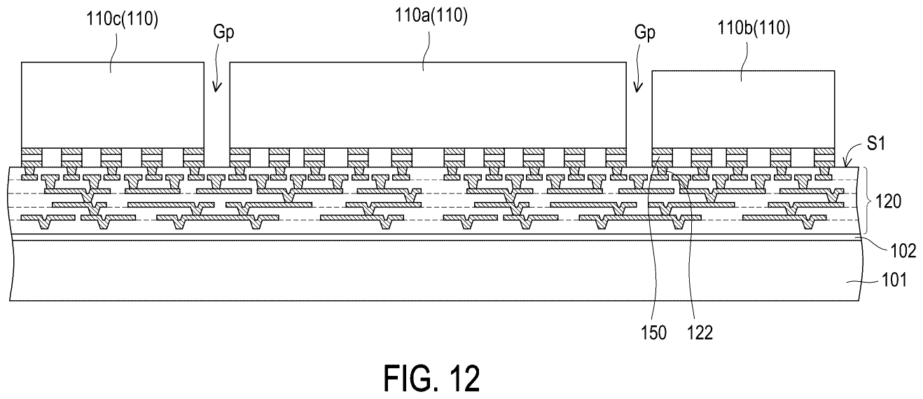

With now reference to FIG. 12, in some embodiments, at least one die 110 is boned on a first side S1 of the redistribution structure 120, for example, through the conductive bumps 150 by flip-chip bonding technique. In some embodiments, more than one dies 110 (e.g., dies 110a, 110b, 110c) may be placed on the conductive bumps 150 using, for example, a pick-and-place tool. In the present embodiment, three dies 110a, 110b, 110c are illustrated herein, but more or less dies may be applied to the device package 100. The disclosure is not limited thereto. The dies 110 are disposed on the carrier 101 in a side-by-side manner. Accordingly, at least one gap Gp exists between any two adjacent dies 110. Herein, two gaps Gp are illustrated, but more or less gap may be applied according to the number of the dies 110. In some embodiments, the dies 110a may be a logic die, such as a system on chip (SOC), a system on integrated chip (SoIC), application specific integrated circuit (ASIC), or the like. The dies 110b, 110c may be memory dies, such as a DRAM die, SRAM die, or the like. Other types of dies may also be adopted, such power management dies (e.g., power management integrated circuit (PMIC) dies), radio frequency (RF) dies, sensor dies, micro-electro-mechanical-system (MEMS) dies, signal processing dies (e.g., digital signal processing (DSP) die), front-end dies (e.g., analog front-end (AFE) dies), transceiver (TRX) dies, the like, or a combination thereof. In addition, the dies 110a, 110b, 110c may be in different sizes (e.g., different heights and/or surface areas), and in other embodiments, the dies 110a, 110b, 110c may be in the same size (e.g., same heights and/or surface areas). In an embodiment, the dies 110 are bonded to the first side S1 of the redistribution structure 120 by a reflow process. During this reflow process, the conductive bumps 150 are in contact with the dies 110, and the pads (UBM layer) of the redistribution structure 120 to physically and electrically couple the dies 110 to the redistribution structure 120.

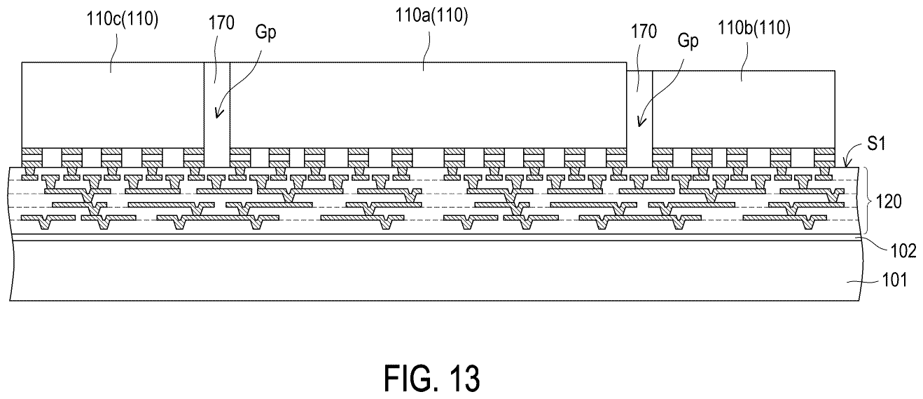

With now reference to FIG. 13, a filling material 170 is provided to at least fill the gaps Gp between the dies 110. In an embodiment, the filling material 170 is dispensed into the gaps Gp between the dies 110 and surrounding the conductive bumps 150. Then, a thermal process is performed to set (cure) the filling material 170. In some embodiments, the filling material 170 may extend up along sidewall of the dies 110. The filling material 170 may be any acceptable material, such as a polymer, epoxy, molding underfill, or the like. In the present embodiment, the filling material includes underfill material, but the disclosure is not limited thereto. The filling material 170 may be formed by a capillary flow process after the dies 110 are attached, or may be formed by a suitable deposition method before the dies 110 are attached. In such embodiment, the filling material 170 fills the gaps Gp between the dies 110, and may partially cover or not cover the outermost side surfaces of the die 110 as it is shown in FIG. 13.

Referring to FIG. 14, an encapsulating material 130 may be optionally provided over the redistribution structure 120 to at least laterally encapsulate the dies 110 in accordance with some embodiments. Then, a thermal process is performed to set the encapsulating material 130. The encapsulating material 130 may include a molding compound, an epoxy, or a resin, etc. In some embodiments, a top surface of the encapsulating material 130 may be higher than back surfaces of the dies 110. Namely, the encapsulating material 130 covers the back surfaces of the dies 110.

Then, a thinning process, which includes a grinding process, may be performed to thin the encapsulating material 130 (and the filling material 170) until the back surfaces of the dies 110 are revealed. The resulting structure is shown in FIG. 14. Due to the thinning process, the back surfaces of the dies 110 are substantially level with the upper surfaces of the filling material 170, and are substantially level with the upper surface of the encapsulating material 130 as shown in FIG. 5. Throughout the description, the resultant structure including the dies 110, the filling material 170, the encapsulating material 130 (optional), and the redistribution structure 120 as shown in FIG. 14 is referred to as a package wafer PK, which may have a wafer form in the process.

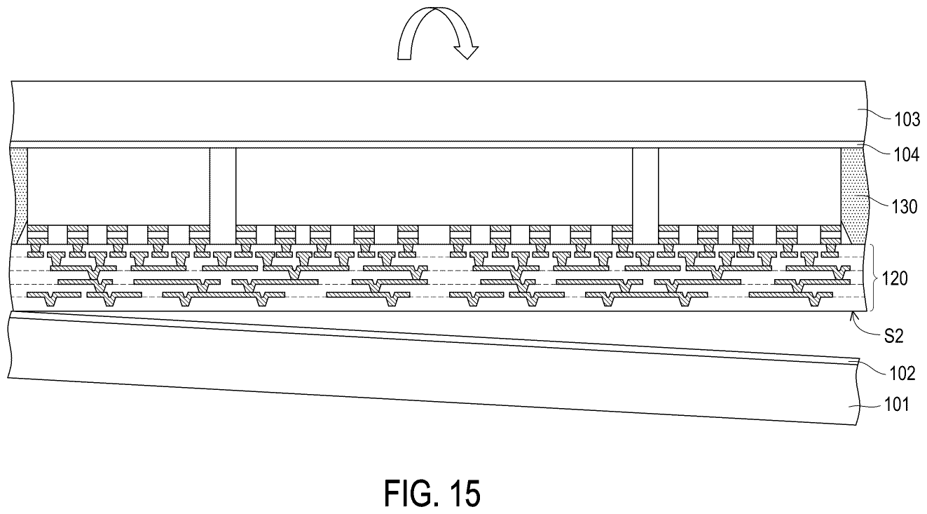

With now reference to FIG. 14 and FIG. 15, an upper side of the package wafer PK is now temporarily attached to another carrier 103 by an adhesive layer 104 for supporting the package wafer PK during subsequent processing. In some embodiments, the carrier 103 may be glass, ceramic, alumina, stainless steel or another material that provides adequate temporary support for the package wafer PK during processing. A demounting step is performed to remove the carrier 101 from a second side S2 of the redistribution structure 120. In some embodiments, the carrier 101 is detached from the second side S2 of the redistribution structure 120 by causing the adhesive layer 102 to lose or reduce adhesion. The adhesive layer 102 is then removed along with the carrier 101. For example, the adhesive layer 102 may be exposed to UV light, so that the adhesive layer 102 loses or reduces adhesion, and hence the carrier 101 and the adhesive layer 102 can be removed from the second side S2 of the redistribution structure 120. It is noted that the orientation in the figures is shown for purposes of illustration only, and the process could be performed with the structure oriented in another direction.

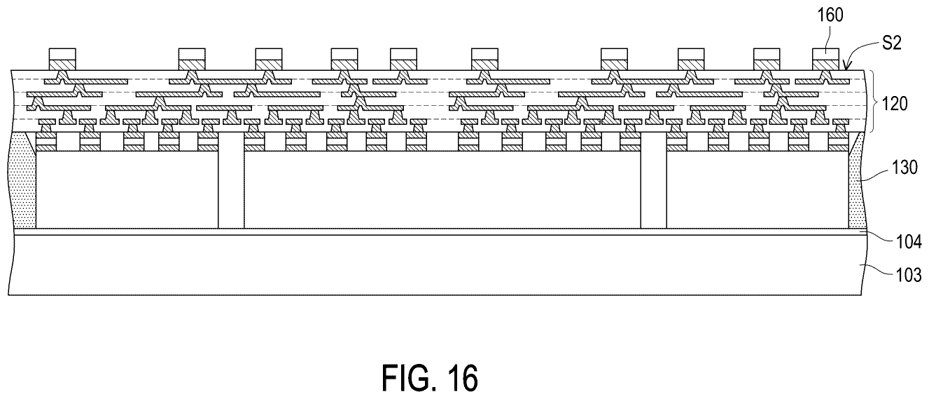

In FIG. 16, the orientation of the package wafer PK is flipped, and the connectors 160 are provided over the second side S2 of the redistribution structure 120. Again, the orientation in the figures is shown for purposes of illustration only, and the process could be performed with the structure oriented in another direction. In some embodiments, the connectors 160 may be solder balls, metal pillars, controlled collapse chip connection (C4) bumps, micro bumps, electroless nickel-electroless palladium-immersion gold technique (ENEPIG) formed bumps, combination thereof (e.g., a metal pillar having a solder ball attached thereof), or the like. The connectors 160 may include a conductive material such as solder, copper, aluminum, gold, nickel, silver, palladium, tin, the like, or a combination thereof. In some embodiments, the connectors 160 include a eutectic material and may comprise a solder bump or a solder ball, as examples. In some embodiments, a reflow process may be performed, giving the connectors 160 a shape of a partial sphere in some embodiments. Alternatively, the connectors 160 may comprise other shapes. The connectors 160 may also comprise non-spherical conductive connectors, for example. In some embodiments, the connectors 160 include metal pillars (such as a copper pillar) formed by a sputtering, printing, electro plating, electroless plating, CVD, or the like, with or without a solder material thereon. The metal pillars may be solder free and have substantially vertical sidewalls or tapered sidewalls. In the present embodiment, the connectors are C4 bumps, but the disclosure is not limited thereto.

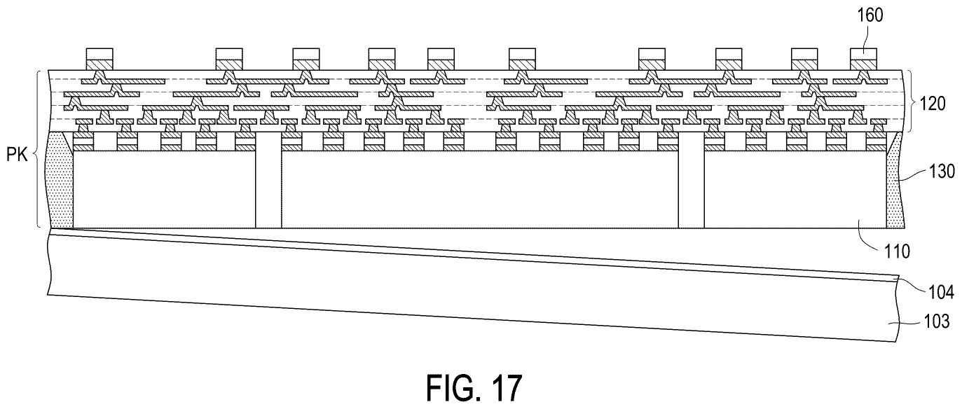

With now reference to FIG. 17, a demounting step is performed to remove the carrier 103 from the package wafer PK. In some embodiments, the carrier 103 is detached from the package wafer PK by causing the adhesive layer 104 to lose or reduce adhesion. The adhesive layer 104 is then removed along with the carrier 103. For example, the adhesive layer 104 may be exposed to UV light, so that the adhesive layer 104 loses or reduces adhesion, and hence the carrier 103 and the adhesive layer 104 can be removed from the package wafer PK.

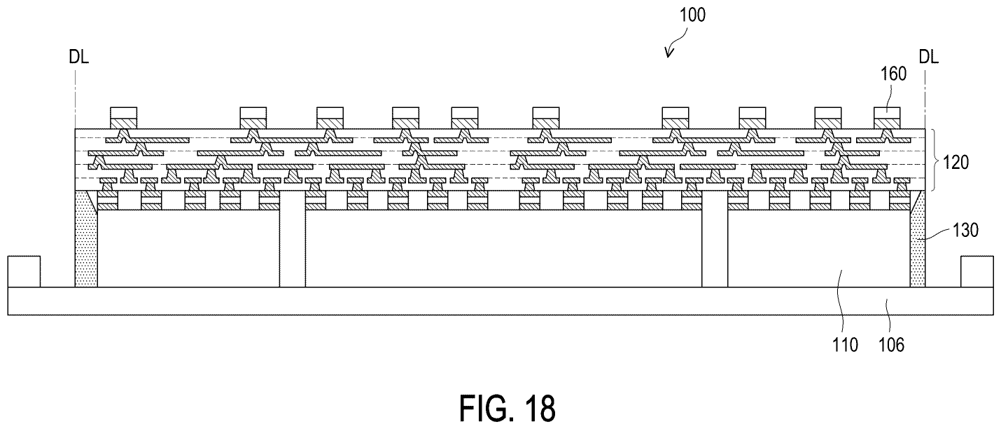

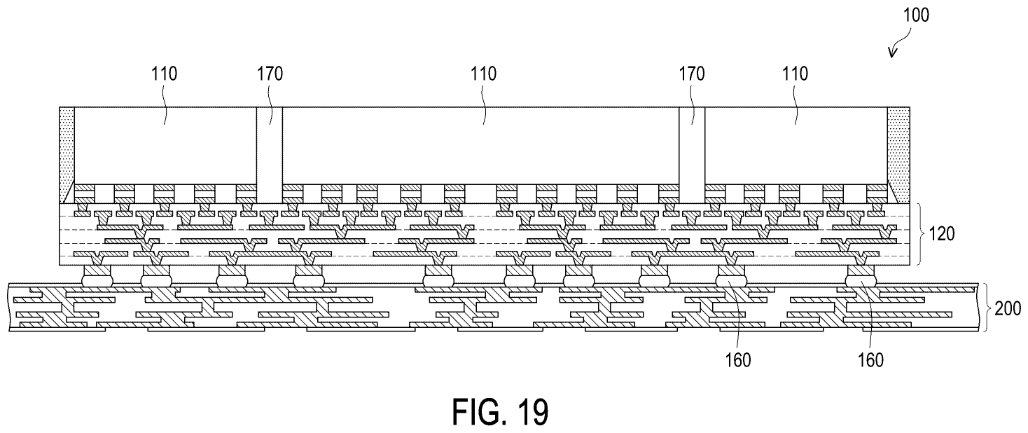

Referring to FIG. 18, the package wafer PK may then be mounted (e.g. frame mounted) onto a dicing tape 106. Following this, a singularization process is performed, so that the package wafer PK may be singulated or diced (e.g. along dicing line DL), thereby forming a plurality of device packages 100, each of which may be substantially identical to the device package 100 shown in FIG. 19.

With reference now to FIG. 19, after the device package 100 is formed, the device package 100 may be disposed on the substrate 200 through, for example, a pick and place technique. In some embodiments, the connectors 160 are aligned to, and are put against, bond pads of the substrate 200. The connectors 160 may be reflowed to create a bond between the substrate 200 and the device package 100. The substrate 200 may include a package substrate, such as a build-up substrate including a core therein, a laminate substrate including a plurality of laminated dielectric films, a PCB, or the like. The substrate 200 may include electrical connectors (not shown), such as solder balls, opposite the component package to allow the substrate 200 to be mounted to another device.

Then, as illustrated in FIG. 20, an underfill material 230 can be dispensed between the device package 100 and the substrate 200 and surrounding the connectors 160 to form the package structure 105. The underfill material 230 may be any acceptable material, such as a polymer, epoxy, molding underfill, or the like. In some embodiments, the underfill material 230 may be the same material as the filling material 170. In other embodiments, the underfill material 230 may be the different material from the filling material 170.

It is note that, in an alternative embodiment, the device package 100 may be an Integrated Fan-Out (InFO) package including at least one device die encapsulated by an encapsulating material and a redistribution structure disposed over the device die and the encapsulating material. In other embodiments, the structure of the package structure 105 may be a CoWoS® (Chip on Wafer on Substrate) package including a plurality of device dies encapsulated by an encapsulating material and mounted over an interposer on the substrate. However, the disclosure is not limited thereto. Other suitable packages and component configurations may also be applied.

Based on the above discussions, it can be seen that the present disclosure offers various advantages. It is understood, however, that not all advantages are necessarily discussed herein, and other embodiments may offer different advantages, and that no particular advantage is required for all embodiments.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In accordance with some embodiments of the disclosure, a semiconductor package includes a substrate, a semiconductor device disposed over the substrate, a ring structure bonded to the substrate, and a lid structure bonded to the ring structure. The ring structure includes a main portion surrounding the semiconductor device and a cantilever portion extended toward the semiconductor device and bonded to a top surface of the semiconductor device. The lid structure includes a contact portion bonded to the top surface of the semiconductor device. In one embodiment, the lid structure includes a flange portion connecting the contact portion, and the flange portion is bonded to the cantilever portion and the main portion. In one embodiment, a thickness of the contact portion is greater than a thickness of the flange portion. In one embodiment, the semiconductor package further includes a thermal interface material disposed between the contact portion and the semiconductor device for thermally coupling the semiconductor device and the lid structure. In one embodiment, the ring structure further includes a rib extended across a space surrounded by the main portion and bonded to the lid structure. In one embodiment, the rib includes an upper portion extended toward and bonded onto the semiconductor device. In one embodiment, a width of the rib is substantially greater than a width of the main portion. In one embodiment, the semiconductor device includes a plurality of first dies surrounding a second die, and the rib is disposed between the second die and the plurality of first dies. In one embodiment, the semiconductor device further includes an encapsulating material laterally encapsulating the plurality of first dies to form a device package. In one embodiment, the contact portion includes a plurality of contact portions bonded to the second die and the device package respectively.

In accordance with some embodiments of the disclosure, a semiconductor package includes a package structure, a ring structure, and a lid structure. The package structure includes a substrate and a semiconductor device disposed over the substrate. The ring structure is disposed over the substrate and surrounds the semiconductor device, wherein a cross section of the ring structure is in inverted L shape, and the ring structure is bonded to a first part of the top surface of the package structure. The lid structure is disposed over the ring structure and bonded to a second part of the top surface of the package structure. In one embodiment, the ring structure includes a main portion surrounding the semiconductor device and a cantilever portion extended toward the semiconductor device and bonded to the first part of the top surface of the semiconductor device. In one embodiment, the semiconductor package further includes an adhesive disposed over the cantilever portion and the main portion for bonding the lid structure to the ring structure. In one embodiment, the lid structure includes a contact portion bonded to the second part of the top surface of the package structure and a flange portion surrounding the contact portion, and the flange portion is bonded to the cantilever portion and the main portion. In one embodiment, an area of an upper surface of the ring structure bonding to the lid structure is greater than an area of a lower surface of the ring structure bonding to the substrate. In one embodiment, the semiconductor device includes a plurality of first dies surrounding a second die, and the ring structure further includes a rib disposed between the second die and the plurality of first dies. In one embodiment, the rib comprises an upper portion extended toward and bonded onto the semiconductor device.

In accordance with some embodiments of the disclosure, a manufacturing method of a semiconductor package includes the following steps. A semiconductor device is provided onto a substrate. A first adhesive is provided over the substrate and a top surface of the semiconductor device. A ring structure is bonded onto the substrate, wherein the ring structure includes a main portion surrounding the semiconductor device and a cantilever portion bonded to a first part of the top surface of the semiconductor device. A second adhesive is provided over the cantilever portion and the main portion. A lid structure is bonded over the ring structure and a second part of the top surface of the semiconductor device. In one embodiment, the semiconductor device includes a device package having a plurality of first dies encapsulated by an encapsulating material and a second die, the ring structure further includes a rib extended between the plurality of first dies and the second die, and the lid structure is bonded to the rib. In one embodiment, formation of the device package includes: providing a plurality of first dies over a redistribution structure; providing filling material for filling gaps between the plurality of first dies; providing an encapsulating material laterally encapsulating the plurality of first dies; and performing a singularization process to form the device package.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a substrate;
a semiconductor device disposed over the substrate;
a ring structure bonded to the substrate, wherein the ring structure comprises a main portion surrounding the semiconductor device and a cantilever portion extending toward the semiconductor device and bonded to a top surface of the semiconductor device; and
a lid structure bonded to the ring structure and comprising a contact portion bonded to the top surface of the semiconductor device.

2. The semiconductor package as claimed in claim 1, wherein the lid structure comprises a flange portion connecting the contact portion, and the flange portion is bonded to the cantilever portion and the main portion.

3. The semiconductor package as claimed in claim 2, wherein a thickness of the contact portion is greater than a thickness of the flange portion.

4. The semiconductor package as claimed in claim 1, further comprising a thermal interface material disposed between the contact portion and the semiconductor device for thermally coupling the semiconductor device and the lid structure.

5. The semiconductor package as claimed in claim 1, wherein the ring structure further comprising a rib extended across a space surrounded by the main portion and bonded to the lid structure.

6. The semiconductor package as claimed in claim 5, wherein the rib comprises an upper portion extended toward and bonded onto the semiconductor device.

7. The semiconductor package as claimed in claim 5, wherein a width of the rib is substantially greater than a width of the main portion.

8. The semiconductor package as claimed in claim 5, wherein the semiconductor device comprises a plurality of first dies surrounding a second die, and the rib is disposed between the second die and the plurality of first dies.

9. The semiconductor package as claimed in claim 8, wherein the semiconductor device further comprises an encapsulating material laterally encapsulating the plurality of first dies to form a device package.

10. The semiconductor package as claimed in claim 9, wherein the contact portion comprises a plurality of contact portions bonded to the second die and the device package respectively.

11. A semiconductor package, comprising:
a package structure comprising a substrate and a semiconductor device disposed over the substrate;
a ring structure disposed over the substrate and surrounding the semiconductor device, wherein a cross section of a sidewall of the ring structure is in inverted L shape, and the ring structure is bonded to a first part of the top surface of the package structure; and
a lid structure disposed over the ring structure and bonded to a second part of the top surface of the package structure.

12. The semiconductor package as claimed in claim 11, wherein the ring structure comprises a main portion surrounding the semiconductor device and a cantilever portion extended toward the semiconductor device and bonded to the first part of the top surface of the semiconductor device.

13. The semiconductor package as claimed in claim 12, further comprising an adhesive disposed over the cantilever portion and the main portion for bonding the lid structure to the ring structure.

14. The semiconductor package as claimed in claim 12, wherein the lid structure comprises a contact portion bonded to the second part of the top surface of the package structure and a flange portion surrounding the contact portion, and the flange portion is bonded to the cantilever portion and the main portion.

15. The semiconductor package as claimed in claim 11, wherein an area of an upper surface of the ring structure bonding to the lid structure is greater than an area of a lower surface of the ring structure bonding to the substrate.

16. The semiconductor package as claimed in claim 11, wherein the semiconductor device comprises a plurality of first dies surrounding a second die, and the ring structure further comprises a rib disposed between the second die and the plurality of first dies.

17. The semiconductor package as claimed in claim 16, wherein the rib comprises an upper portion extended toward and bonded onto the semiconductor device.

18. A manufacturing method of a semiconductor package, comprising:
disposing a semiconductor device on a substrate;
bonding a ring structure onto the substrate, wherein the ring structure comprises a main portion surrounding the semiconductor device and a cantilever portion bonded to a first part of the top surface of the semiconductor device;
providing an adhesive over the cantilever portion and the main portion; and
bonding a lid structure over the ring structure and a second part of the top surface of the semiconductor device.

19. The semiconductor package as claimed in claim 18, wherein the semiconductor device comprises a device package having a plurality of first dies encapsulated by an encapsulating material and a second die, the ring structure further comprising a rib extended between the plurality of first dies and the second die, and the lid structure is bonded to the rib.

20. The semiconductor package as claimed in claim 19, wherein formation of the device package comprises:
providing a plurality of first dies over a redistribution structure;
providing filling material for filling gaps between the plurality of first dies;
providing an encapsulating material laterally encapsulating the plurality of first dies; and
performing a singularization process to form the device package.
